(19) United States
(12) Patent Application Publication
(10) Pub. No.: US 2012/0138115 A1
(43) Pub. Date: Jun. 7, 2012

(54) SURFACE EXCITONIC THERMOELECTRIC DEVICES

(75) Inventor: Yong Chen, West Lafayette, IN (US)

(73) Assignee: PURDUE RESEARCH FOUNDATION, West Lafayette, IN (US)

(21) Appl. No.: 13/312,986

(22) Filed: Dec. 6, 2011

Related U.S. Application Data
(60) Provisional application No. 61/419,998, filed on Dec. 6, 2010.

(51) Int. Cl. H01L 35/32

(52) U.S. Cl. 136/205

(57) ABSTRACT

A thermoelectric device is disclosed. The device includes an insulating layer, a first conducting layer configured to induce charge of a first polarity on a first surface of the insulating layer, and a second conducting layer configured to induce charge of a second polarity on a second surface of the insulating layer, the second polarity opposite the first polarity, and the first surface opposite the second surface across a transversal axis, wherein by induction of opposing charges on the first surface and the second surface of the insulating layer spatially separated surface excitons are formed on the first and the second surfaces of the insulating layer, the spatially separated surface excitons generate a counterflow electrical current when a thermal gradient is provided across a longitudinal axis of the insulating layer. The surface excitons could potentially condense into a superfluid under appropriate conditions, giving rise to superfluidic thermoelectric current.

### PRIORITY

The present application is related to, and claims the priority benefit of, U.S. Provisional Patent Application Ser. No. 61/419,998 filed Dec. 6, 2010, the content of which is hereby incorporated in its entirety into the present disclosure.

### TECHNICAL FIELD

The present disclosure generally relates to thermoelectric power generation and microcooling and particularly to thermoelectric devices with high performance using specific surface qualities of topological insulator materials and other materials capable to host spatially separated excitons.

### BACKGROUND

A significant amount of power consumed around the world is converted to heat and released, wastefully. For example, thermal energy is lost when lighting an incandescent light bulb. Although some researchers have investigated ways to reuse the lost thermal energy, currently, a significant amount of the electrical, fossil fuel, nuclear energy, and the like are lost to heat. Use of thermoelectric material is one way to recover the lost thermal energy.

Thermoelectric devices positioned between hot and cold reservoirs can be used to generate electrical power. Conversely applying electrical power to thermoelectric devices can be used to transfer heat for various cooling applications, e.g., microcooling applications.

The basis for thermoelectric power conversion is commonly referred to as the Seebeck effect, named after the discoverer of this phenomenon. For a small amount of thermal gradient at the junction of two materials (e.g., thermal gradient between a hot body and a cold body), i.e., AT=TH−Tc, a small voltage, AV is generated between the two materials, according to the formula

S=AV/AT,

wherein S is the Seebeck coefficient. As for the absolute value of the Seebeck coefficient, it is desirable to find material with higher Seebeck coefficients. As for the sign of the Seebeck coefficient (i.e., whether it is a positive number or a negative number) depends on whether carriers between the hot body and the cold body are electrons or holes.

Referring to FIG. 9, a schematic of a conventional thermoelectric system 10 according to the prior art is depicted. The thermoelectric system 10 includes a cold reservoir 12 (indicated by T_{L}) and a hot reservoir 14 (indicated by T_{H}). A bulk p-doped thermoelectric material 11A and a bulk n-doped thermoelectric material 11b are positioned between the cold and hot reservoirs 12 and 14. Holes 17 and electrons 19 provide a flow of holes and electrons from the hot reservoir 14 to the cold reservoir 12, generating an electrical current 18 from the hot reservoir 14 to the cold reservoir 12 in the p-doped thermoelectric material, and a counterflow electrical current 20 in the n-doped thermoelectric material from the cold reservoir 12 to the hot reservoir 14. A load resistor (device) 13 completes the circuit.

Besides the Seebeck coefficient, other factors, particularly thermal and electrical conductivities of the material also play a role for operation of the thermoelectric system 10. The overall efficiency measure for thermoelectric materials is the Figure of Merit (commonly expressed as ZT). The formula for ZT is as follows:

ZT=S²·σ·T·κ⁻¹

wherein S is the Seebeck coefficient,
σ is the electrical conductivity,
κ is thermal conductivity, and
T is the temperature.

It is desirable to maximize ZT. In order to maximize the ZT, the thermoelectric material should have a large Seebeck coefficient, large electrical conductivity, and small thermal conductivity. Therefore, the selection of thermoelectric material requires balancing the need for low thermal conductivity and high electrical conductivity. Having a low thermal conductivity is also important to minimize heat transfer from the hot reservoir to the cold reservoir, since such a heat transfer would eliminate or reduce the same thermal gradient that is producing the electrical power.

Depending on the material properties, different ZT values are achieved. Bismuth telluride (Bi₂Te₃) is a known bulk thermoelectric material suitable for thermoelectric conversion. State of the art ZT is around 1 for Bi₂Te₃ and between 1-3 for more complicated nanostructured materials involving Bi₂Te₃. Practical thermoelectric devices based on these materials have further lower ZT values due to peripheral effects. However, even the maximum state of the art ZT of about 3 is still low for practical cooling applications, such as solid state cooling.

Therefore, there is a need to develop a new thermoelectric device that provides a ZT value of above 3.

### SUMMARY

A thermoelectric device is disclosed. The device includes an insulating layer. The device also includes a first conducting layer configured to induce charge of a first polarity on a first surface of the insulating layer. The device further includes a second conducting layer configured to induce charge of a second polarity on a second surface of the insulating layer, the second polarity is opposite the first polarity, and the first surface is opposite the second surface across a transversal axis. By induction of opposing charges on the first surface and the second surface of the insulating layer spatially separated surface excitons are formed on the first and the second surfaces of the insulating layer, the spatially separated surface excitons generate a counterflow electrical current when a thermal gradient is provided across a longitudinal axis of the insulating layer. The surface excitons could potentially condense into a superfluid under appropriate conditions, giving rise to superfluidic thermoelectric current

A thermoelectric system is disclosed. The system includes a back-gate voltage source, and a front-gate voltage source. The system also includes a thermoelectric device. The device includes an insulating layer. The thermoelectric device also includes a first conducting layer configured to induce charge of a first polarity on a first surface of the insulating layer. The device further includes a second conducting layer configured to induce charge of a second polarity on a second surface of the insulating layer, the second polarity is opposite the first polarity, and the first surface is opposite the second surface across a transversal axis. By induction of opposing charges on the first surface and the second surface of the insulating layer spatially separated surface excitons are formed on the first and the second surfaces of the insulating layer, the spatially separated surface excitons generate a counterflow electrical current when a thermal gradient is provided across a longitudinal axis of the insulating layer. The surface excitons could potentially condense into a superfluid under appropriate conditions, giving rise to superfluidic thermoelectric current

### BRIEF DESCRIPTION OF DRAWINGS

FIG. 1 is a schematic of a thermoelectric system including a thermoelectric device having a topological insulator, according to one embodiment of the present disclosure.

FIG. 2 is a schematic perspective view of the thermoelectric device depicted in FIG. 1 defining a dual-gated topological surface state field effect device (TSFED), wherein front and back conducting surface channels (hosting topological surface states) are independently gated and can be gated to host p-type and n-type carriers respectively.

FIG. 3 is a cross sectional schematic view of the TSFED of FIGS. 1 and 2, according to the present disclosure.

FIG. 4 is a graph of figure of merit (ZT) vs. electrical resistivity measured in ohm meter that can be achieved as calculated in a model for the TSFED based on excitonic counterflow achieved from thermal diffusion resulting in high ZT and based on surface excitonic condensate superfluid counterflow resulting in superior ZT.

FIG. 5 is a schematic of the TSFED device depicted in FIGS. 1-3 positioned between a hot and a cold reservoir and operating based on excitonic counterflow achieved from thermal diffusion.

FIG. 6 is a schematic of the TSFED device depicted in FIGS. 1-3 positioned between a hot and a cold reservoir and operating based on surface excitonic condensate superfluid counterflow.

FIG. 7 is a cross sectional schematic view of a dual topological insulator thermoelectric device for operation based on surface exciton thermal diffusion counterflow and surface excitonic condensate superfluid counterflow, according to another embodiment of the present disclosure.

FIG. 8 is a cross sectional schematic view of a layered thermoelectric device based on two high electrical conductivity layers with opposite polarity carriers sandwiching a thin insulator layer for operation based on surface excitonic condensate superfluid counterflow, according to yet another embodiment of the present disclosure.

FIG. 9 is a schematic of a typical thermoelectric system based on bulk thermoelectric material found in prior art including a hot reservoir and a cold reservoir and bulk p and n doped thermoelectric material establishing an electrical current (with counterflow in the bulk p and n doped materials).

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

The new thermal electric devices disclosed here are based on a novel approach in generating electrical current utilizing high conductivity surface states (or high conductivity surface layers) of insulators that lead to significantly improved ZT compared to values achieved in the prior art. Three embodiments are described. In each of the three embodiments, one or multiple insulating layers are used. The term insulating layer (or insulator) refers to electrical insulation, i.e., high electrical resistivity, in the bulk. In the first embodiment, a double gated single topological insulator thermoelectric device is described. In the second embodiment, a double gated—double insulating layers, each having a topological insulator, thermoelectric device is described. In the third embodiment, two high electrical conductivity layers sandwiching about an insulator, thermoelectric device is described. In the third embodiment, the insulating layer is not a topological insulator. In each of these embodiments, surface excitonic pairs of electron-holes allow flow of electrical current with reduced electrical resistivity resulting in improved figure of merit (ZT). An exciton is defined by an electron bound to a hole (with the electron in the conduction band, and the hole in the valence band; in the case of surface excitons, the bands refer to those of the surfaces). Furthermore in each of the three embodiments, the thermoelectric device can be configured to form surface excitonic condensates to allow extreme high electrical conductivity on the surface of the insulators providing extraordinarily high ZT. When the effective mass of the electrons (holes) making up the excitons vanishes (as is the case with surface Dirac fermions) exciton condensation has been predicted to occur at temperatures potentially as high as room temperature, for the type of experimentally accessible exciton densities. The state of excitons condensate is analogous to a superconductor state with vanishingly low resistivity, and gives the ability to produce extraordinary high ZT with the counterflow superfluidic thermoelectric current.

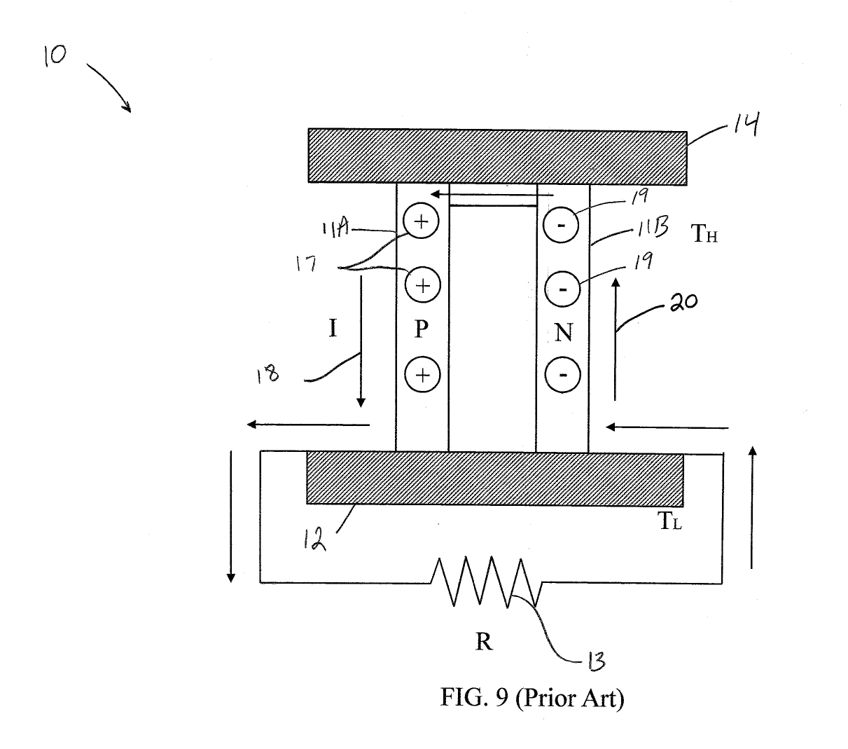

Bi2Te3, Bi2Se3 and various other more complex compounds have been recently shown to belong to a novel class of materials known as topological insulators (TI). TI materials are bulk semiconductors (substantially insulators), but with non-trivial conducting surface states that are topologically protected (as a result of the unique band structures and strong spin orbit coupling in these materials) with high mobility and Dirac fermion dispersion. TI materials such as Bi2Te3 have already been known to be excellent (bulk) thermal electric materials (e.g., see FIG. 9).

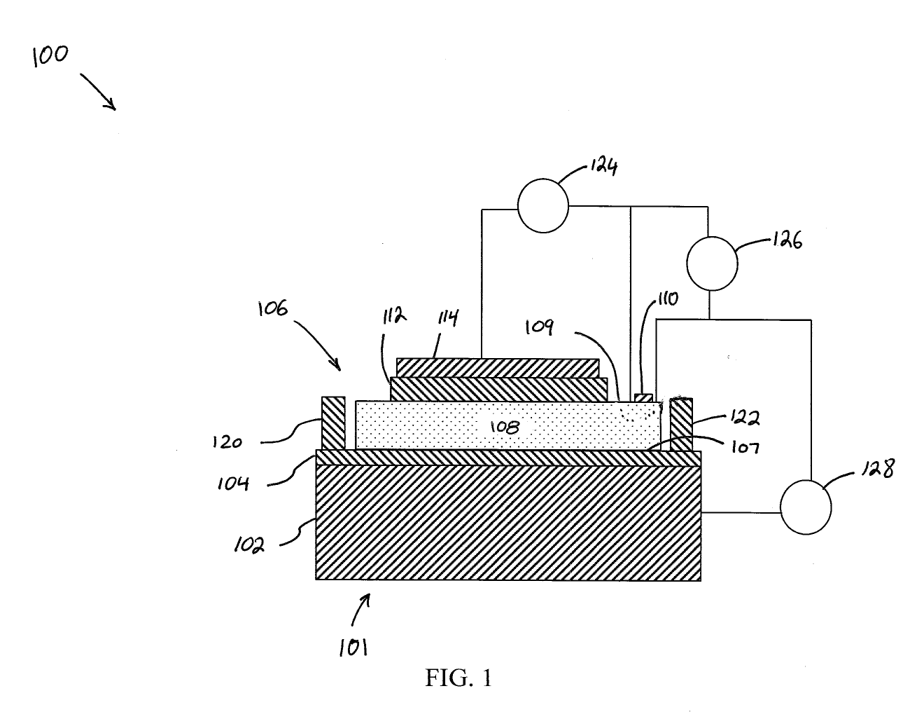

Referring to FIG. 1, a schematic of a thermoelectric system 100, according to one embodiment of the present disclosure, is depicted. The thermoelectric system 100 includes a thermoelectric device 101 positioned between a hot reservoir 120 and a cold reservoir 122. It should be appreciated that the term reservoir is only intended to indicate a source of thermal energy (for the hot reservoir 120) and a sink for thermal energy (the cold reservoir 122) when the thermoelectric system 100 is used to generate electrical power. However, the thermoelectric system 100 can also be used to provide cooling by application of electrical power. In such an embodiment, the hot reservoir 120 and the cold reservoir 122 indicate the state of thermal transfer, i.e., heat transfer from the hot reservoir 120 to the cold reservoir 122 when electrical power is provided to the thermoelectric system 100, as described further below.

The thermoelectric system 100 also includes voltage sources 124 and 128. The polarities of the voltage sources 124 and 128 are opposite from one another. Therefore, for example, if the voltage source 124 provides a positive voltage, the complementary voltage source 128 provides a negative voltage. This is assuming that initially there are no surface state carriers on the top and bottom surfaces of the topological insulator 106 controlled by the voltages 124 and 128 respectively; otherwise one just needs to add appropriate voltage offsets to the gate voltages to compensate for the initial carrier densities. A sensing voltmeter 126 (also referred to as the reference voltage) is positioned between the two voltage sources 124 and 128. The sensing voltmeter 126 in one aspect (where the thermoelectric system 100 is configured to cool, e.g., in a microcooling application) can be used to power the thermoelectric device. However, in another aspect (where the thermoelectric system 100 is configured to generate electrical power) can be view as a sensing device to measure the amount of electrical voltage that is generated or electrical power delivered to an electrical load, as is described further below.

The thermoelectric device 101 includes a conducting substrate 102 (also referred to as conducting layer). The conducting substrate 102 may be formed from various substrates including doped silicon, or other commonly known substrate material in the semiconductor arts. The conducting substrate 102 is also referred to as the back-gate. The conducting substrate 102 is a type of conducting substrate where a connector (not shown) can be connected to it in order to transfer charge from a voltage source, e.g., the voltage source 128, to the substrate material. In particular, the voltage 128 is connected to the conducting substrate 102 via a connector (not shown). It should also be appreciated that if the conducting substrate is a semiconductor type substrate, then the substrate is doped. The doping type of the conducting substrate 102 can be either n-type or p-type for the operation of the thermoelectric device. Examples of the conducting substrate 102 are a doped silicon (Si) or gallium arsenide (GaAs), graphite/graphene, etc. Alternatively, the conducting substrate 102 can be a metal layer. Exemplary and common type metals are gold (Au), aluminum (Al), copper (Cu), etc. Furthermore, the conducting substrate 102 can also be a substrate that is strongly electrically polarizable, e.g., STO (SrTiO₃).

The thermoelectric device 101 further includes a dielectric layer 104 disposed over the conducting layer 102. The dielectric layer 104 can be made from a range of dielectric material commonly used in the semiconductor industry such as silicon oxide (SiO₂), aluminum oxide (Al₂O₃), hafnium Oxide (HfO₂), undoped wide gap semiconductors such as aluminum arsenic (AlAs), aluminum gallium arsenic (AlGaAs), boron nitride (BN), etc. The dielectric layer 104 is configured to allow capacitive coupling of charge between the conducting substrate 102 and a topological insulator 106 disposed adjacent the dielectric layer 104. Therefore, the combination of the conducting substrate 102, the dielectric layer 104, and the topological insulator 106 constitutes a sort of capacitor that allows charge (either electrons or holes) to be distributed over the bottom surface of the topological insulator 106 as further described below. It should be noted that the hot reservoir 120 and the cold reservoir 122 provide a thermal gradient across a longitudinal axis of the topological insulator 106.

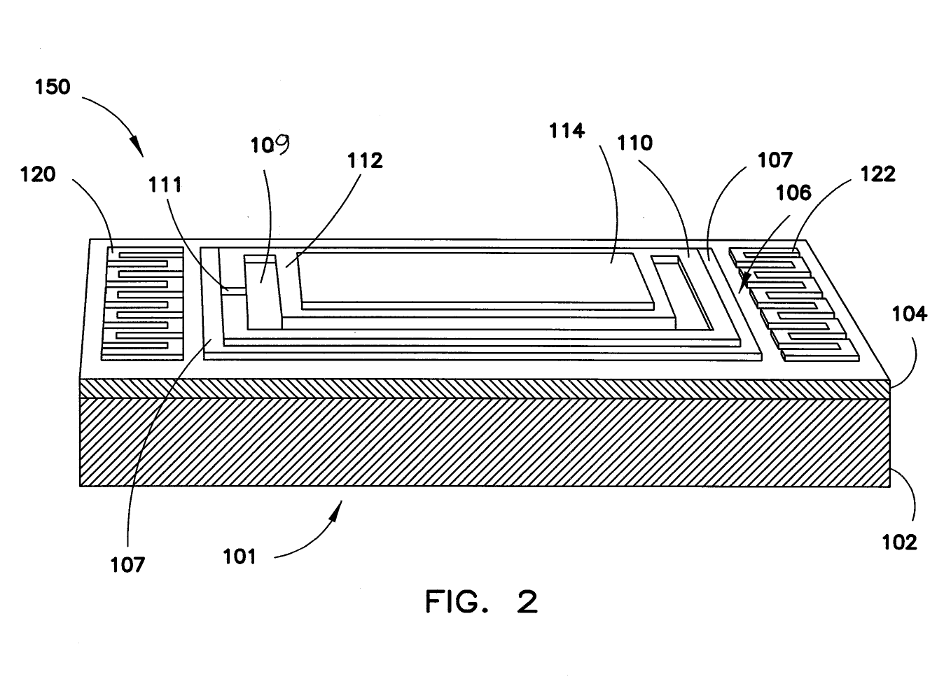

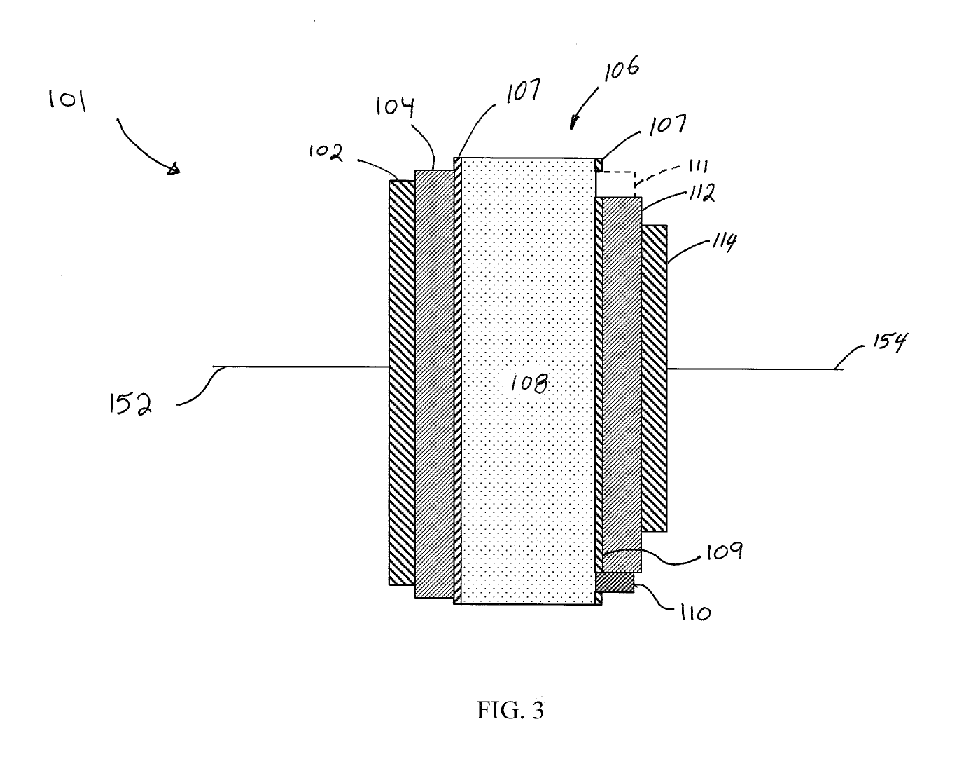

As described above, the topological insulator 106 is surrounded by a conducting surface having states that are topologically protected (as a result of the unique band structures and strong spin orbit coupling in these materials) with high mobility and Dirac fermion dispersion. While the band dispersion (the energy as a function of the momentum for electrons in the conduction band, or holes in the valence band) is governed by a quadratic function in traditional semiconductor material, the dispersion for the electrons or holes in the surface states of the topological insulator 106 is governed by a linear function. Such linearly dispersing electrons or holes are known as Dirac fermions, and are also predicted to have high mobility (conductivity) due to the special spin-momentum locking properties of the topological insulator surface states. Furthermore, excitons form by pairing these Dirac electrons and holes from two coupled topological insulator surfaces (in one embodiment, the opposite surfaces of the topological insulator 106, i.e., surfaces 107 and 109, see FIG. 2), where 107 refers to the bottom surface, which is electrically connected via the side surface to a portion of the top surface identified by the reference numeral 107) can condense into a superfluid at higher temperature than is commonly thought with excitons in known semiconductors. These surfaces of the topological insulator 106 are identified by reference numerals 107 and 109 (see FIGS. 2 and 3). It should be appreciated that while the surfaces 107 and 109 (see FIG. 3) are depicted as separate members (cross-hatched) as compared to the material inside the surfaces, the surfaces 107 and 109 are simply the outside surfaces of the topological insulator 106 as the surface 107 constitutes the bottom surface of the topological insulator 106 and the surface 109 constitutes the top surface of the topological insulator 106 (inside the insulating member 111), where these surface 107 and 109 are opposite each other across a transversal axis that crosses the thickness of the topological insulator 106 and therefore the surfaces 107 and 109 represents no additional material other than the topological insulator 106 (i.e., material inside the surfaces 107 and 109, identified by reference numeral 108). In order to isolate the charges (electrons and holes) that are formed on these surfaces 107 and 109, a small insulating member 110 is provided on these surfaces 107 and 109. The insulating member 110 can be a magnetic insulating material with a notch 111 (shown in FIG. 2) utilized to render the conducting surface states directly underneath the magnetic insulating material 110 insulating, thus providing substantial electrical isolation (except at the notch, which was placed to electrically connect the top and bottom surfaces 107 and 109 at one end) of the surfaces 107 and 109 of the topological insulator 106. It should be noted that FIG. 1 is a cross sectional view of FIG. 2 with the section being taken through the notch 111 so that on one side (left side) the notch is not seen and on the other side (right hand side) only a small portion of insulating member 110 is seen. Example material for the insulating members 110 can be magnetically doped semiconductor (e.g., GaMnAs, ZtMnTe, etc.), and ferromagnetic insulators (e.g., EuO, spinels, Gd-based compounds, etc.).

With the surfaces 107 and 109 isolated, the reference voltage 126 can be coupled to one or another side of the surfaces 107 or 109 (surface 109 is depicted to be coupled to the high side of reference voltage 126 while surface 107, which includes the entire bottom surface, is depicted to be coupled to the bottom side of reference voltage 126). Material examples of the topological insulator 106 include Bi₂Te₃, Bi₂Se₃, Sb₂Te₃, Bi₁₋ₓSbₓ, strained HgTe thin films, various tertiary/quartenary/mixed compounds in chalcogenides/chalcopyrites/heuslers/pyrochlore family such as Bi₂Te₂Se (“BTS221”), Bi₂Te₂S; Bi—Sb—Te, Bi—Sb—Te—Se, Tl(Bi,Sb)(Te,Se,S)₂, PbBi₂Se₄, PbSb₂Te₅, and generally AB₂C₄, A₂B₂C₅, MN₄C₇, A₂C₂C′ [A/B=Pb/Ge/Sb/Bi, M/N=Pb/Bi], etc.

The thermoelectric device 101 further includes a dielectric 112 disposed between the topological insulator 106 and a front-gate 114. The front-gate 114 may be formed from various substrates including doped silicon, metals, or other commonly known conducting material in the semiconductor arts. The front-gate 114 is a type of conducting material where a connector (not shown) can be connected to it in order to transfer charge from a voltage source, e.g., the voltage source 124, to the conducting material. In particular, the voltage 124 is connected to the front-gate 114 via a connector (not shown). It should also be appreciated that if the front-gate 114 is a semiconductor type material, then the material is doped. The doping type of the front-gate 114 is not important, just as in the case of the back gate material 102. Examples of the front-gate 114 are a doped silicon (Si) or gallium arsenide (GaAs), graphene, graphite, etc. Alternatively, the front-gate 114 can be a metal layer. Exemplary and common type metals are gold (Au), aluminum (Al), copper (Cu), etc. Furthermore, the conducting substrate 102 can also be a material that is strongly electrically polarizable, e.g., STO (SrTiO₃). When using such strong polarizable material or substrate for the back gate 102 or front gate 114, the gate dielectric 104 or 112 is optional.

The dielectric layer 112 can be made from a range of dielectric material commonly used in the semiconductor industry such as silicon oxide (SiO₂), aluminum oxide (Al2O3), hafnium Oxide (HfO2), undoped wide gap semiconductors such as aluminum arsenic (AlAs), aluminum gallium arsenic (AlGaAs), boron nitride (BN), etc. The dielectric layer 112 is configured to allow capacitive coupling of charge between the front-gate 114 and the topological insulator 106 disposed adjacent the dielectric layer 112. Therefore, the combination of the front-gate 114, the dielectric layer 112, and the topological insulator 106 constitutes a sort of capacitor that allows charge (either electrons or holes) to be distributed over the top surface of the topological insulator 106 as further described below.

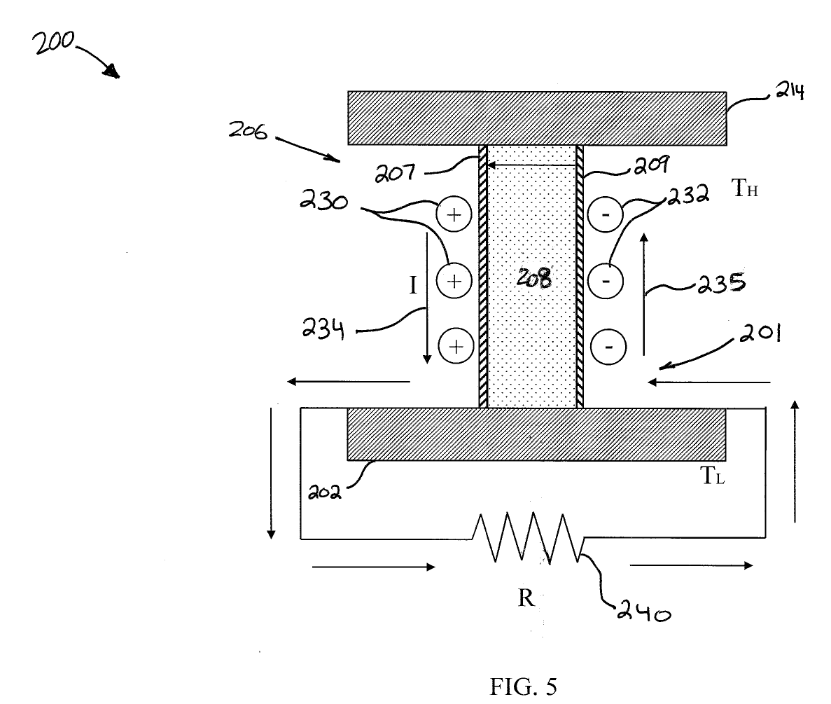

The two gates, i.e., the back-gate 102 and the front-gate 114, result in charges (electrons and holes) to be distributed over the surfaces 107 (bottom side of the topological insulator 106) and 109 (the area inside the insulating member 110). It should be appreciated that due to the capacitive coupling of these gates 102 and 114 and the topological insulator 106, negligible electrical current pass through the gates 102 and 114 through the dielectric layers 104 and 112 to the topological insulator 106. The capacitive coupling provides the needed charge carriers of opposite polarity on the opposite surfaces 107 and 109 of the topological insulator 106 to establish a counterflow electrical current 234 (see FIG. 5 described below). The electrical current 234 remains while the gates 102 and 114 are charged appropriately to induce the opposite polarity charges on the opposite surfaces and there is a thermal gradient, i.e., the hot and cold reservoirs 120 and 122 are disposed adjacent the topological insulator 106. The charges on the surfaces 107 and 109 are electron hole pairs which are referred to as surface excitonic, as described further below.

Referring to FIG. 2, a schematic perspective view of the thermoelectric device 101 depicted in FIG. 1 defining a dual-gated topological surface state field effect device (TSFED), wherein front and back conducting surface channels (hosting topological surface states) are independently gated and can be gated to host p-type and n-type carriers respectively is depicted. The combination of the thermoelectric device 101 and the hot and cold reservoirs 120 and 122 is depicted as a thermoelectric subsystem 150. The hot and cold reservoirs 120 and 122 may also include temperature measuring sensors (not shown) such as thermocouples to measure temperatures at these reservoirs 120 and 122.

Applying equal and opposite gate voltages controlling the two surface channels (assuming they initially have no surface state carriers; otherwise one just needs to add a voltage offset to the gate voltages to compensate for the initial carrier densities) in the dual gated thermoelectric device 101 shall induce topological surface excitons. The amplitude of the gate voltage controls the exciton density. Should such excitons condense into excitonic condensates (occurs when the separation between the two coupled surfaces, i.e., the thickness of the topological insulator 106, is small enough and when the temperature is below the condensation temperature), described further below, coherent tunneling could occur between the two surfaces and the counterflow electrical transport becomes superfluidic. These can be easily detected in transport measurements. Excitonic condensates can also be detected in optical measurement of surface excitation spectra.

Referring to FIG. 2, the insulating member 110 is more clearly depicted providing an electrical isolation of the surfaces 107 and 109. While not shown, the top side of the reference voltage 126 (see FIG. 1) is coupled to the surface 109 (between the top surface inside the electrical isolation strip 110) while the bottom side of the reference voltage 126 is coupled to the surface 107 (mostly the bottom surface of the topological insulator 106 and the area outside the insulating member 110), with voltage sources 124 and 128 being coupled to the front-gate 114 and the back-gate 102, respectively.

The TSFED structure of the thermoelectric device 101 depicted in FIG. 2 can be used to induce topological surface state excitons (electron-hole pairs), when the two gates induce equal and opposite carriers (electrons and holes) in the two surfaces 107 and 109 of the topological insulator 106.

Referring to FIG. 3, a cross sectional schematic view of the thermoelectric device 101 depicted in FIG. 1 defining the TSFED is depicted. The structures depicted in FIG. 3 from left to right are the back-gate 102 (also referred to as the conducting substrate 102 or the conducting layer), the dielectric layer 104, the topological insulator 106 with surfaces 107 and 109, the dielectric layer 112, and the front-gate 114 (also referred to as the conducting substrate 114 or the conducting layer). The conducting layer 102 is coupled to the voltage source 128 (see FIG. 1) via the wire 152 and the front-gate 114 is coupled to the voltage source 124 (see FIG. 1) via the wire 154.

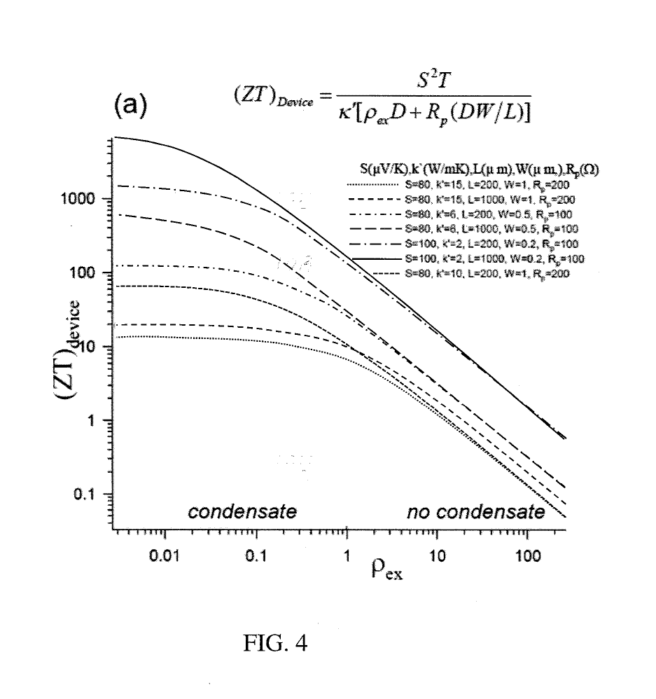

Referring to FIG. 4, a graph of figure of merit (ZT) vs. electrical resistivity measured in ohm meter that can be achieved as calculated in a model for the TSFED thermoelectric device 101 based on excitonic counterflow achieved from thermal diffusion resulting in high ZT, and based on surface excitonic condensate superfluid counterflow resulting in superior ZT, is depicted. The right hand side of the graph depicted in FIG. 4 describes the relationship between ZT and the electrical resistivity for one class of thermoelectric devices according to the present disclosure based on excitonic counterflow achieved from thermal diffusion. This portion of the graph is identified as “no condensate”. The left hand side of the graph of FIG. 4 describes the relationship between ZT and the electrical resistivity for another class of thermoelectric devices according to the present disclosure based on formation of excitonic condensates resulting in extremely low resistivity translating to extraordinary measures of ZT. Formation of excitonic condensates is further described below in greater detail. As can be seen the measure of ZT even in the no condensate portion can be significantly higher (ZT of about 10) than achieved by bulk thermoelectric material utilizing the best known bulk thermoelectric material (i.e., ZT achieved in the range of 1-3). Therefore, the concept of improved conductivity by surface excitonic transport achieved from thermal diffusion of topological insulator surface Dirac electrons and holes resulting in high ZT is by itself useful over the known techniques for thermoelectric systems.

The graphs of FIG. 4 are based on a formula for calculating ZT in a device model, as follows:

$${( ZT )}_{Device} = \frac{{S}^{2} T}{{κ}^{′} [ {ρ}_{ex} D + {R}_{p} ( DW / L ) ]}$$

wherein S is the Seebeck coefficient (the example values shown in the figure are measured in μV/K),
κ′ is the total effective thermal conductivity of the device including peripheral thermal shunt (e.g., dielectric/gate/substrate), with example values measured in W/mK,
ρₑₓ is the surface resistivity of excitonic transport measured in ohm/square,
D is the thickness of the topological insulator layer, taken to be 10 nm in this calculated example,
Rₚ is the total peripheral resistance (contact resistance and resistance of portion of topological insulator surface connecting but not part of excitonic device channels), with example values measured in ohms,
W is channel width (as defined by the gates) of the topological insulator (with example values measured in μm), and
L is the channel length (as defined by the gates) of the topological insulator (with example values measured in μm). Based on various values (representing examples of realistic device structures) described in FIG. 4, the ZT is shown to be extraordinarily high with formation of excitonic condensates, i.e., well above 10 and particularly as high as 1000.

Referring to FIG. 5, is a schematic of a thermoelectric system 200 including a partial TSFED device 201 similar to the one depicted in FIGS. 1-3 positioned between a hot reservoir 214 and a cold reservoir 202 and operating based on excitonic counterflow achieved from thermal diffusion is depicted. The TSFED device 201includes a topological insulator 206 having surfaces 207 and 209 (surrounding material 208). Surface excitonic charges (pairs of electrons 232 and holes 230) form on opposite sides of the topological insulator 206 on the surfaces 207 and 209 generating a current and counterflow current 234-235 that can be used to provide electrical power used by a load 240.

As discussed above, significant enhancement of ZT (value in excess of about 5-10) can be achieved with this thermoelectric device configuration depicted in FIG. 5 due to ultrahigh electronic mobility/conductivity of topological protected surface state carriers, and enhanced power factor of low-d (2D) systems (while the thermal conductivity of the TI remains to be dominated by the bulk and being low, such as in Bi2Te3).

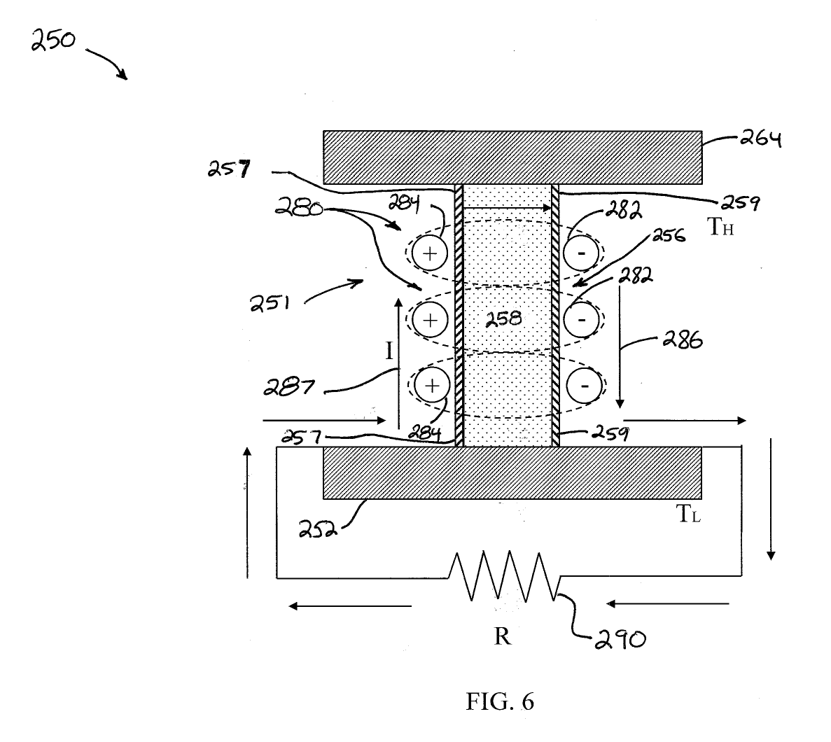

Referring to FIG. 6, a schematic of thermoelectric system 250 including a partial TSFED device 251 positioned between a hot reservoir 264 and a cold reservoir 252 and operating based on surface excitonic condensate superfluid counterflow is depicted. The TSFED device 251 includes a topological insulator 256 having surfaces 257 and 259 surrounding material 258. Surface excitonic condensates (pairs of electrons 282 and holes 284 that condense into an excitonic superfluid) form on opposite sides of the topological insulator 256 on the surfaces 257 and 259 generating a superfluidic current and counterflow current 286-287 that can be used to provide electrical power used by a load 290. The excitonic condensates are referenced by the reference numeral 280 and are depicted by oval dashed lines.

Condensates of electron pairs have been known as a basis for superconductivity. In superconductors, two electrons bind into a boson (commonly known as a Cooper pair). These bosons then undergo what is commonly referred to as a Bose-Einstein condensation. In principle, the phenomenon should be possible with electron and holes pairs (excitons) instead of two electrons. In this case, the attraction between the fermions is not a phonon-mediated effect, but the Coulomb attraction between particles with positive and negative charges.

Referring to FIG. 6, the schematic is of a novel topological excitonic condensate thermoelectric device (TEC²), based on a predicted topological excitonic condensate (EC) in ultrathin (less than 10 nm, where the small thickness enhances the coupling and pairing between the electrons and holes when forming the excitons and in turn enhance the temperature at which exciton condensation can occur) topological insulator (TI) films with oppositely gated surfaces is depicted. The TEC² device depicted in FIG. 6 is the same device structure as the topological surface excitonic thermoelectric device depicted in FIG. 5, but its operation is based on superfluid counterflow (driven by the thermal gradient) of condensed excitons (electron-holes pairs) on coupled topological insulator surfaces. This superfluid counterflow in charge-neutral exciton condensate is an electronic analogue of a thermomechanic “fountain effect” in superfluids, known to a person having ordinary skill in the art. Utilized in thermoelectric transport, this dissipationless counterflow can produce orders of magnitude increase in ZT (e.g., greater than about 1000), and would be only limited by parasitic (e.g., contact resistance) and thermal excitations in superfluids.

The schematic of the TEC² device depicted in FIG. 6 (with predicted possible room-temperature condensation temperature due to high-energy scales of massless Dirac fermions of topological surface states) could provide various super-low power devices. Exemplary devices include a “BisFET” device based on coherent tunneling, and dissipationless CMOS interconnent. If superflow is utilised for thermal electric transport, TEC devices with orders-of magnitude increase in ZT than current known values (i.e., ZT values of 1-3 seen in bulk-type thermoelectric devices) can be realized. The counterflow supercurrent driven by thermal gradient is a distinct feature of the charge neutral condensate (superfluid) of spatially decoupled excitons and is an electronic analogue of fountain effect in superfluid helium-4. It should be noted that such fountain effect does not occur in usual superconductors of condensed electron cooper pairs due to large excitation energy gaps.

Referring back to FIG. 4, the left hand side of the graph of FIG. 4 describes the relationship between ZT and the surface electrical resistivity based on formation of excitonic condensates resulting in extremely low resistivity translating to extraordinary measures of ZT. For various values of the elements describing ZT as a function of resistivity, several curves are generated, each of which plateaus to a maximum value ZT (the saturation is due to peripheral resistances such as contacts) that is much higher than the ZT obtained from the surface excitonic (non-condensed) effect of topological insulator.

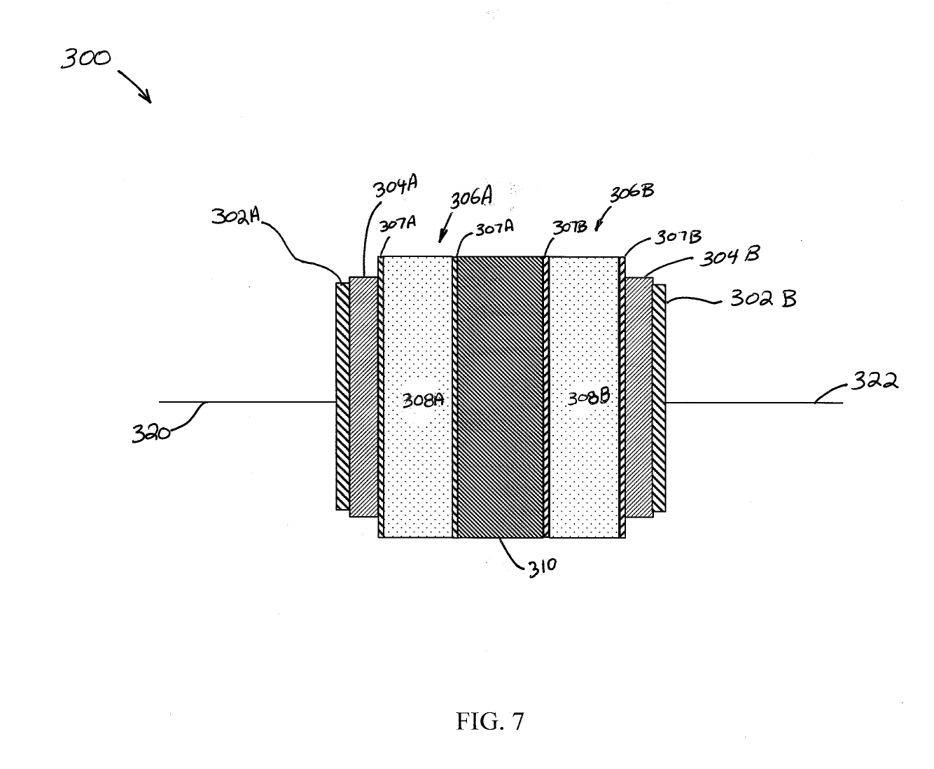

Referring to FIG. 7, a cross sectional schematic view of a thermoelectric device 300 is depicted. The structures depicted in FIG. 7 from left to right are a back-gate 302A (i.e., a conducting substrate or conducting layer) similar to the conducting layer 102 depicted in FIG. 1), a dielectric layer 304A, a topological insulator 306A with surfaces 307A (only front and back surfaces are depicted for clarity, although it should be appreciated the surfaces 307A continuously wrap around and over of the topological insulator 306A (including the portion 308A) and in this embodiment; the side surfaces (not shown) do not affect the operation of the device), an insulator 310, a topological insulator 306B with surfaces 307B (only front and back surfaces are depicted for clarity, although it should be appreciated the surfaces 307B continuously wrap around the entire surface of the topological insulator 306B (including the portion 308B) and in this embodiment; the side surfaces (not shown) do not affect the operation of the device), a dielectric layer 304B, and a front-gate 302B. The back-gate (conducting substrate) 302A is coupled to a voltage source (similar to the voltage source 128 depicted in FIG. 1) via the wire 320. The front-gate 302B is coupled to a voltage source (similar to the voltage source 124 depicted in FIG. 1) via the wire 322. Surface excitons form between opposite polarity charges on the surfaces 307A and 307B generating a counterflow current based on excitonic transport achieved from thermal diffusion. Alternatively, excitonic condensates can form on the surface 307A and 307B generating extraordinarily high ZT.

Examples of the conducting substrate (i.e., front-gate and back-gate) 302A and 302B are a doped silicon (Si) or gallium arsenide (GaAs), graphite/graphene, etc. Alternatively, the conducting substrates 302A and 302B can each be a metal layer. Exemplary and common type metals are gold (Au), aluminum (Al), copper (Cu), etc. Furthermore, the conducting substrates (layers) 302A and 302B can also be layers that are strongly electrically polarizable, e.g., STO (SrTiO₃).

The dielectric layers 304A and 304B can be made from a range of dielectric material commonly used in the semiconductor industry such as silicon oxide (SiO₂), aluminum oxide (Al2O3), hafnium Oxide (HfO2), undoped wide gap semiconductors such as aluminum arsenic (AlAs), aluminum gallium arsenic (AlGaAs), boron nitride (BN), etc. The dielectric layer 304A is configured to allow capacitive coupling of charge between the back-gate 302A and the topological insulator 306A disposed adjacent the dielectric layer 304A. The dielectric layer 304B is configured to allow capacitive coupling of charge between the front-gate 302B and the topological insulator 306B disposed adjacent the dielectric layer 304B. Therefore, the combination of the back-gate 302A, the dielectric layer 304A, and the topological insulator 306A constitutes a sort of capacitor that allows charge (either electrons or holes) to be distributed over the surfaces 307A of the topological insulator 306A. Similarly, the combination of the front-gate 302B, the dielectric layer 304B, and the topological insulator 306B constitutes a sort of capacitor that allows charge (either holes or electrons of opposite polarity from the charges on surface 307B to allow excitons to form) to be distributed over the surfaces 307B of the topological insulator 306B. The thickness of the topological insulator 306A and 306B will be kept to be sufficiently thin (<10 nm) so the entire surface 307A or 307B (particularly the surface adjacent to the insulator 310 on each side) can be controlled by the corresponding gate 302A or 302B. The thickness of the insulator 310 will be kept thin (<10 nm) to ensure sufficient strength of Coulomb coupling between the surface electrons and holes when forming excitons and to facilitate excitonic condensation driven by such coupling.

Material examples of the topological insulator 306 include Bi₂Te₃, Bi₂Se₃, Sb₂Te₃, Bi₁₋ₓSbₓ, strained HgTe thin films, various tertiary/quartenary/mixed compounds in chalcogenides/chalcopyrites/heuslers/pyrochlore family such as Bi₂Te₂Se (“BTS221”), Bi₂Te₂S; Bi—Sb—Te, Bi—Sb—Te—Se, Tl(Bi,Sb)(Te,Se,S)₂, PbBi₂Se₄, PbSb₂Te₅, and generally AB₂C₄, A₂B₂C₅, MN₄C₇, A₂C₂C′ [A/B=Pb/Ge/Sb/Bi, M/N=Pb/Bi], etc.

This structure (where two topological insulators are separated by a conventional insulator in a sandwich-like structure) is an alternative embodiment (not requiring the bulk of a topological insulator 106 as depicted in FIG. 1 to be strictly insulating, and not requiring to electrically isolate different parts of the surface of one topological insulator as needed in FIG. 1 using the magnetic insulator film). This alternate structure couples one surface of one topological insulator with another surface of another topological insulator, separated by an artificially placed good thin conventional insulator layer 310, instead of coupling the two opposite surfaces of the same topological insulator as depicted in FIG. 1. Each topological insulator in such a hetero structure can be individually gated, and the two topological insulator can also gate each other. Such hetero structures can be grown by techniques such as MBE, MOCVD or ALD that are compatible with conventional semiconductor fabrication and can be used to make topological insulator devices of the present disclosure and facilitate the realization of excitonic condensates states.

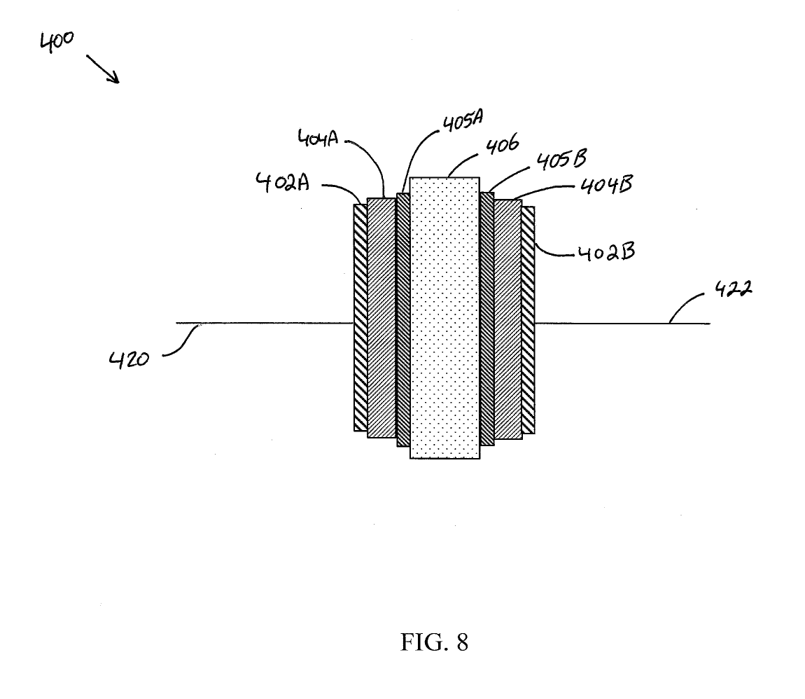

Referring to FIG. 8, a cross sectional schematic view of a thermoelectric device 400 is depicted. The structures depicted in FIG. 8 from left to right are a back-gate 402A (i.e., a conducting layer similar to the conducting layer 102 depicted in FIG. 1), a conventional insulator which can serve as gate dielectric layer 404A (similar to the dielectric layer 104, depicted in FIG. 1), a conducting layer 405A made of an “ambipolar” material (such as graphene) whose charge carriers can be tuned to be either electrons or holes by the gate (i.e., back-gate 402A), a conventional insulator 406, another conducting layer 405B made of the same “ambipolar” material (such as graphene) as 405A however configured to have opposite charge polarity, another gate dielectric 404B, and a front-gate 402B. The back-gate (conducting layer) 402A is coupled to a voltage source (similar to the voltage source 128 depicted in FIG. 1) via a wire 420. The front-gate 402B is coupled to a voltage source (similar to the voltage source 124 depicted in FIG. 1) via a wire 422. Surface excitons (electron-hole pairs) form between the two conducting layers 405A and 405B with opposite charge polarity (electrons and holes), generating a current based on excitonic transport achieved from thermal diffusion. Furthermore, under appropriate conditions (when the separation between the two conducting layers is sufficiently close, inducing strong Coulomb coupling between electrons and holes in the two layers, and in temperatures low enough to below the transition temperature of excitonic condensation), excitonic condensates can form on the coupled conducting layers 405A and 405B generating superfluidic counterflow current and extraordinarily high ZT in the presence of the thermal gradient. It should be appreciated that in this embodiment, the insulator is not a topological insulator, but rather an ordinary insulating material (such as SiO₂, HfO₂, Al₂O₃, BN, etc.) known to a person having ordinary skill in the semiconductor art is used (the thickness of this insulator needs to be sufficiently thin, <10 nm, to allow strong coupling and pairing between the electrons and holes in the conducting layers 405A and 405B adjacent to each side of this insulator to induce excitonic condensation). The material of conducting layers 405A and 405B can be graphene or any “ambipolar” material in which the charge carriers can be tuned to have both polarities (electrons or holes) by gating, allowing formation of excitonic charges between the coupled conducting layers 405A and 405B. The two conducting layers 405A and 405B should use the same type of the material except for the opposite carrier polarity induced by the corresponding gates (402A and 402B). Using graphene, or another “ambipolar” material in which the carriers have Dirac dispersions similar to that in graphene, to form conducting channels has the advantage that exciton condensation for the pairs (excitons) between strongly coupled Dirac electrons and holes are predicted to be high (potentially as high as room temperature). The gate dielectric 404A and 404B, and the gates 402A and 402B, can use similar materials as used in the gate dielectrics 304A, 304B and gates 302A, 302B, respectively, as depicted in FIG. 7.

Topological protection of highly conducting topological insulator surface states, free of elastic back scattering in the absence of magnetic impurities, which are relatively immune to structural imperfections was one rationale for the present disclosure. Topological insulator surface states are analogous with graphene in which both have Dirac fermions with “relativistic” liner energy-momentum dispersion, and can be described by Dirac Hamiltonian. However there is a critical difference that makes TI surface states more favorable in practically fabricated transistor devices than graphene transistors.

In graphene, the Dirac Hamiltonian is based on pseudospin-orbit (momentum) coupling where the pseudospin is related to sublattice indices and valleys. In TI surface states, the form of Dirac Hamiltonian is similar to graphene but the pseudospin is replaced by real spin (spin-orbit coupling in TI materials). Therefore, in graphene the momentum of the carriers is locked to their pseudospin, and short range/sharp defects such as those generated by nanopatterning or edge roughness in graphene nanoribbons give rise to backscattering, thus are detrimental to conductivity/mobility. However, on TI surfaces, the momentum is locked to real-spin (via spin-orbit coupling). Thus backscattering requires spin-flip, and thus requires (much more rare) magnetic impurities. In contrast, non-magnetic defects such as the structural defects or edge roughness in a TI nanoribbon will have much less effect on conductivity/mobility as compared to their effect in graphene. This relative insensitiveness to structural defects makes TI particularly promising for energy-efficient nanoelectronic devices.

It should be noted that the TSFED device depicted in FIG. 1 does not require nor assumes excitonic condensation (EC). The device can be built with technologies currently familiar to a person having ordinary skill in the art, and further be based upon experimentally established novel topologically protected surface state properties. The device described in FIG. 1 can already result in significantly improved low power energy-efficient electronic devices.

Those skilled in the art will recognize that numerous modifications can be made to the specific implementations described above. Therefore, the following claims are not to be limited to the specific embodiments illustrated and described above. The claims, as originally presented and as they may be amended, encompass variations, alternatives, modifications, improvements, equivalents, and substantial equivalents of the embodiments and teachings disclosed herein, including those that are presently unforeseen or unappreciated, and that, for example, may arise from applicants/patentees and others.

1. A thermoelectric device, comprising:
an insulating layer;
a first conducting layer configured to induce charge of a first polarity on a first surface of the insulating layer; and
a second conducting layer configured to induce charge of a second polarity on a second surface of the insulating layer, the second polarity opposite the first polarity, and the first surface opposite the second surface across a transversal axis,
wherein by induction of opposing charges on the first surface and the second surface of the insulating layer spatially separated surface excitons are formed between the first and the second surfaces of the insulating layer, the spatially separated surface excitons generate a counterflow electrical current when a thermal gradient is provided across a longitudinal axis of the insulating layer.

2. The thermoelectric device of claim 1, wherein the insulating layer is substantially electrically insulating.

3. The thermoelectric device of claim 2, wherein the insulating layer is substantially thermally insulating.

4. The thermoelectric device of claim 3, wherein the insulating layer is a topological insulator.

5. The thermoelectric device of claim 4, wherein the topological insulator is formed from one of Bi₂Te₃, Bi₂Se₃, Sb₂Te₃, Bi₁₋ₓSbₓ, strained HgTe thin films, Bi₂ Te₂Se, Bi₂Te₂S, Bi—Sb—Te, Bi—Sb—Te—Se, Tl(Bi,Sb)(Te,Se,S)₂, and PbBi₂Se₄, PbSb₂Te₅.

6. The thermoelectric device of claim 4, wherein the conducting layer is formed from one of doped silicon (Si), doped gallium arsenide (GaAs), graphene, graphite, gold (Au), aluminum (Al), copper (Cu), and SrTiO_{3.}

7. The thermoelectric device of claim 1, further comprising:
a first dielectric layer formed between the first conducting layer and the insulating layer; and
a second dielectric layer formed between the insulating layer and the second conducting layer.

8. The thermoelectric device of claim 7, wherein the first dielectric layer is configured to capacitively couple the first surface of the insulating layer to the first conducting layer and the second dielectric layer is configured to capacitively couple the second surface of the insulating layer to the second conducting layer, wherein applying a first voltage to the first conducting layer can induce charge carriers of a first polarity on the first surface of the insulating layer, and applying a second voltage on the second conducting layer can induce charge carriers of a second polarity on the second surface of the insulating layer, where the first polarity is opposite the second polarity.

9. The thermoelectric device of claim 8, wherein the first and second dielectric layers are formed from one of silicon oxide (SiO2), aluminum oxide (Al₂O₃), hafnium Oxide (HfO₂), boron nitride (BN), aluminum arsenic (AlAs), and aluminum gallium arsenic (AlGaAs).

10. The thermoelectric device of claim 7, further comprising:
a second insulating layer, the second insulating layer being a topological insulator; and
a third insulating layer,
wherein the second dielectric is formed between the second conducting layer and the second insulating layer, and the third insulating layer is formed between the insulating layer and the second insulating layer, and
wherein by induction of opposing charges on the first surface of the insulating layer and a first surface of the second insulating layer, spatially separated surface excitons are formed on the first surface of the first insulating layer and the first surface of the second insulating layer, the spatially separated surface excitons generate a counterflow electrical current when a thermal gradient is provided across the longitudinal axis of the insulating layer.

11. The thermoelectric device of claim 1, wherein surface excitons form excitonic condensates configured to generate flow of electrons and holes at substantially zero electrical resistivity.

12. The thermoelectric device of claim 10, wherein surface excitons form excitonic condensates configured to generate flow of electrons and holes at substantially zero electrical resistivity.

13. A thermoelectric system, comprising:
a back-gate voltage source;
a front-gate voltage source ; and
a thermoelectric device comprising:
an insulating layer;
a first conducting layer configured to induce charge of a first polarity on a first surface of the insulating layer; and
a second conducting layer configured to induce charge of a second polarity on a second surface of the insulating layer, the second polarity opposite the first polarity, and the first surface opposite the second surface across a transversal axis,
wherein by induction of opposing charges on the first surface and the second surface of the insulating layer spatially separated surface excitons are formed on the first and the second surfaces of the insulating layer, the spatially separated surface excitons generate a counterflow electrical current when a thermal gradient is provided across a longitudinal axis of the insulating layer.

14. The thermoelectric system of claim 13, wherein the insulating layer is a topological insulator.

15. The thermoelectric system of claim 14, wherein the topological insulator is formed from one of Bi₂Te₃, Bi₂Se₃, Sb₂Te₃, Bi₁₋ₓSbₓ, strained HgTe thin films, Bi₂Te₂Se, Be₂Te₂S, Bi—Sb—Te, Bi—Sb—Te—Se, Tl(Bi,Sb)(Te,Se,S)₂, and PbBi₂Se₄, PbSb₂Te₅.

16. The thermoelectric system of claim 14, wherein the conducting substrate is formed from one of doped silicon (Si), doped gallium arsenide (GaAs), graphene, graphite, gold (Au), aluminum (Al), copper (Cu), and SrTiO₃.

17. The thermoelectric system of claim 14, the thermoelectric device further comprising:
a first dielectric layer formed between the first conducting layer and the insulating layer; and
a second dielectric layer formed between the insulating layer and the second conducting layer.

18. The thermoelectric system of claim 17, wherein the first dielectric layer is configured to capacitively couple the first surface of the insulating layer to the first conducting layer and the second dielectric layer is configured to capacitively couple the second surface of the insulating layer to the second conducting layer, wherein applying a first voltage to the first conducting layer can induce charge carriers of a first polarity on the first surface of the insulating layer, and applying a second voltage on the second conducting layer can induce charge carriers of a second polarity on the second surface of the insulating layer, where the first polarity is opposite the second polarity.

19. The thermoelectric system of claim 17, further comprising:
a second insulating layer, the second insulating layer being a topological insulator; and
a third insulating layer,
wherein the second dielectric is formed between the second conducting layer and the second insulating layer, and the third insulating layer is formed between the insulating layer and the second insulating layer, and
wherein by induction of opposing charges on the first surface of the insulating layer and a first surface of the second insulating layer, spatially separated surface excitons are formed on the first surface of the first insulating layer and the first surface of the second insulating layer, the spatially separated surface excitons generate a counterflow electrical current when a thermal gradient is provided across the longitudinal axis of the insulating layer.

20. The thermoelectric system of claim 13, wherein surface excitons form excitonic condensates configured to generate flow of electrons and holes at substantially zero electrical resistivity.
